(19) United States
(12) Patent Application Publication
(10) Pub. No.: US 2020/0312626 A1
(43) Pub. Date: Oct. 1, 2020

(54) FILM FORMING APPARATUS AND FILM FORMING METHOD

(71) Applicant: Tokyo Electron Limited, Tokyo (JP)

(72) Inventor: Jun YAMAWAKU, Nirasaki City (JP)

(73) Assignee: Tokyo Electron Limited, Tokyo (JP)

(21) Appl. No.: 16/825,077

(22) Filed: Mar. 20, 2020

(30) Foreign Application Priority Data
Mar. 26, 2019 (JP) 2019-057679

(51) Int. Cl. H01J 37/32; C23C 16/455

(52) U.S. Cl. CPC H01J 37/32183; H01J 2237/3321; C23C 16/45536

(57) ABSTRACT

A film forming apparatus includes a high-frequency power supply capable of changing a frequency and a matcher for matching an internal impedance of the high-frequency power supply and a load impedance of a load including plasma. The matcher includes a capacitor having a fixed electrostatic capacitance and connected in series with the load. When the high-frequency power supply starts to supply a high-frequency power at a first frequency, the high-frequency power supply sweeps the frequency of the high-frequency power to be supplied such that reflected waves from the load are minimized. When it is determined that plasma is ignited, the high-frequency power supply changes the frequency of the high-frequency power to be supplied, from a second frequency at which plasma is ignited to a third frequency at which plasma is maintained, and instructs the matcher to perform an adjustment such that the reflected waves are minimized at the third frequency.

### CROSS-REFERENCE TO RELATED APPLICATION

This application is based upon and claims the benefit of priority from Japanese Patent Application No. 2019-057679, filed on Mar. 26, 2019, the entire contents of which are incorporated herein by reference.

### TECHNICAL FIELD

The present disclosure relates to a film forming apparatus and a film forming method.

### BACKGROUND

In a semiconductor device manufacturing process, there is an atomic layer deposition (ALD) method in which a thin unit film, which is substantially a monomolecular layer, is repeatedly stacked on a substrate by switching a plurality of processing gases. In addition, there is a plasma-enhanced atomic layer deposition (PEALD) method using plasma at the time of film formation.

### PRIOR ART DOCUMENT

### Patent Document

Patent Document 1: Japanese Laid-Open Patent Publication No. 2016-528667

### SUMMARY

According to one embodiment of the present disclosure, there is provided a film forming apparatus including: a high-frequency power supply configured to be capable of changing a frequency; and a matcher configured to match an internal impedance of the high-frequency power supply and a load impedance of a load including plasma, the matcher including a capacitor having a fixed electrostatic capacitance and connected in series with the load, wherein, when the high-frequency power supply starts to supply a high-frequency power at a first frequency, the high-frequency power supply sweeps the frequency of the high-frequency power to be supplied such that reflected waves from the load are minimized, and wherein, when it is determined that the plasma is ignited, the high-frequency power supply changes the frequency of the high-frequency power to be supplied, from a second frequency at which the plasma is ignited to a third frequency at which the plasma is maintained, and instructs the matcher to perform an adjustment such that the reflected waves from the load are minimized at the third frequency.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a view illustrating an example of a film forming apparatus according to an embodiment of the present disclosure.

FIG. 2 is a diagram illustrating an example in which a high-frequency power supply and a matcher according to the present embodiment are connected to each other.

FIG. 3 is a diagram illustrating an example of a process from plasma ignition to plasma maintenance in the present embodiment.

FIG. 4 is a diagram illustrating an example of a relationship between frequency and reflectance at the time of plasma ignition and at the time of plasma maintenance in the present embodiment.

FIG. 5 is a diagram illustrating an example of the repetition of plasma ignition in the present embodiment.

FIG. 6 is a diagram illustrating an example of a time-dependent change in an ignition frequency and a specified frequency in the present embodiment.

FIG. 7 is a diagram illustrating an example in which a high-frequency power supply and a matcher are connected to each other in Modification 1.

FIG. 8 is a diagram illustrating an example in which a high-frequency power supply and a matcher are connected to each other in Modification 2.

### DETAILED DESCRIPTION

Hereinafter, embodiments of a film forming apparatus and a film forming method of the present disclosure will be described in detail with reference to the drawings. The technology disclosed herein is not limited by the following embodiments. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments

In a PEALD method, in addition to high-speed switching of a material gas and a reaction gas, it is required to form the reaction gas into a plasma in order to improve the effect of the reaction gas. However, in the case where the reaction gas is formed into the plasma at a high speed by applying high-frequency waves in a reaction chamber, it is difficult to speed up the matching between an internal impedance and a load impedance of the high-frequency power supply due to switching of different types of gases and pressure fluctuation. In the PEALD method in which a dense film is formed in any number of layers, the time required for one film formation affects the throughput of the entire process. Therefore, it is expected that plasma is ignited at a high speed in order to reduce the time required for one film formation.

### [Overall Configuration of Film Forming Apparatus 100]

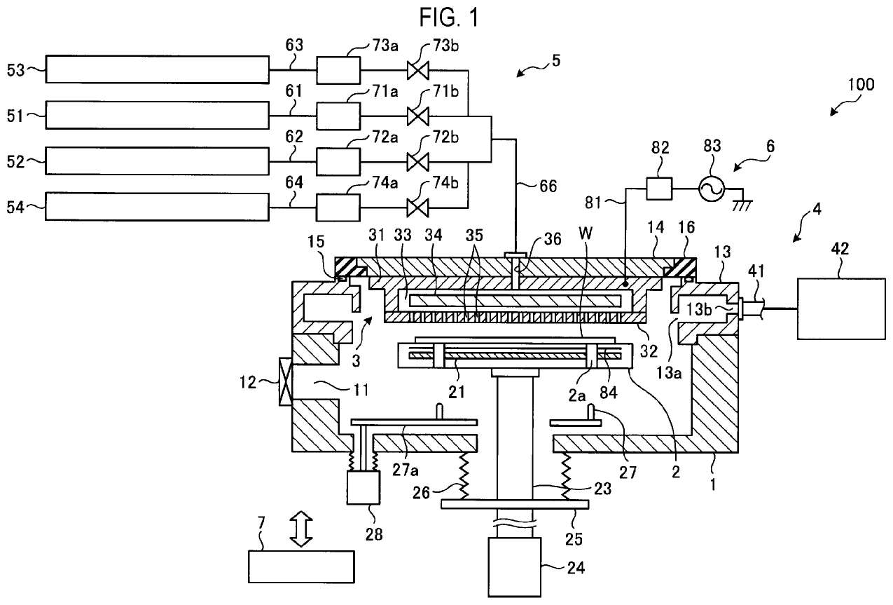

FIG. 1 is a view illustrating an example of a film forming apparatus according to an embodiment of the present disclosure. The film forming apparatus 100 illustrated in FIG. 1 is a capacitively-coupled plasma processing apparatus. The film forming apparatus 100 includes a chamber 1, a susceptor 2 that horizontally supports a wafer W as an example of a substrate to be processed inside the chamber 1, and a shower head 3 configured to supply a processing gas into the chamber 1 in the form of a shower. In addition, the film forming apparatus 100 includes an exhaust part 4 configured to exhaust the interior of the chamber 1, a processing gas supply mechanism 5 configured to supply the processing gas to the shower head 3, a plasma generation mechanism 6, and a controller 7.

The chamber 1 is made of a metal such as aluminum or the like, and is formed in a substantially cylindrical shape. A loading/unloading port 11 through which the wafer W is loaded and unloaded is formed in a sidewall of the chamber 1. The loading/unloading port 11 is opened and closed by a gate valve 12. An annular exhaust duct 13 having a rectangular cross section is provided on a main body of the chamber 1. The exhaust duct 13 has a slit 13a formed along an inner peripheral surface thereof. In addition, an exhaust port 13b is formed in an outer wall of the exhaust duct 13. On an upper surface of the exhaust duct 13, a ceiling wall 14 is provided so as to close an upper opening of the chamber 1. An insulating ring 16 is fitted into an outer periphery of the ceiling wall 14. A space between the insulating ring 16 and the exhaust duct 13 is hermetically sealed by a seal ring 15.

The susceptor 2 is formed in a disk shape having a larger diameter than the wafer W, and is supported by a support member 23. The susceptor 2 is made of a ceramic material such as aluminum nitride (AlN) or the like, or a metallic material such as aluminum, a nickel-based alloy or the like. The susceptor 2 includes a heater 21 embedded therein so as to heat the wafer W. The heater 21 is supplied with power from a heater power supply (not illustrated) to generate heat. By controlling the output of the heater 21 based on a temperature signal of a thermocouple (not illustrated) provided in the vicinity of a wafer placement surface of an upper surface of the susceptor 2, the wafer W is controlled to have a predetermined temperature.

The support member 23 that supports the susceptor 2 extends downward of the chamber 1 from the center of the bottom surface of the susceptor 2 through a hole formed in a bottom wall of the chamber 1. A lower end of the support member 23 is connected to a lifting mechanism 24. The susceptor 2 is configured to be raised and lowered between a processing position illustrated in FIG. 1 and a transfer position defined below the processing position and at which the wafer W can be transferred, by the lifting mechanism 24 through the support member 23. A flange member 25 is provided on the support member 23 at a position below the chamber 1. Between the bottom surface of the chamber 1 and the flange member 25, there is provided a bellows 26 configured to isolate an internal atmosphere of the chamber 1 from ambient air and to be flexible with the vertical movement of the susceptor 2.

Three wafer support pins 27 (of which only two are illustrated) are provided in the vicinity of the bottom surface of the chamber 1 so as to protrude upward from a lifting plate 27a. The wafer support pins 27 are configured to be raised and lowered by a lifting mechanism 28 provided below the chamber 1, via the lifting plate 27a. The wafer support pins 27 are inserted into respective through-holes 2a provided in the susceptor 2 located at the transfer position and are moved upward and downward on the upper surface of the susceptor 2. By raising and lowering the wafer support pins 27 in this manner, the wafer W is delivered between a wafer transfer mechanism (not shown) and the susceptor 2.

The shower head 3 is made of a metal and provided to face the susceptor 2. The shower head 3 is fixed to the ceiling wall 14 of the chamber 1, and includes a main body 31 having a gas diffusion space 33 defined therein and a baffle plate 34 disposed inside the gas diffusion space 33.

In the center of an upper wall of the main body 31, a gas introduction hole 36 connected to the gas diffusion space 33 is formed. In addition, the gas introduction hole 36 is also formed continuously in the ceiling wall 14. A pipe (to be described later) of the processing gas supply mechanism 5 is connected to the gas introduction hole 36. A lower surface of the main body 31 is configured as a shower plate 32 having a plurality of gas ejection holes 35 formed therein. The gas diffusion space 33 may have a diameter larger than that of the wafer W.

The baffle plate 34 has a disk shape, and is provided so as not to be in contact with the lower surface of the upper wall and an inner surface of the sidewall of the main body 31 and an inner surface of the shower plate 32. The baffle plate 34 has a function of guiding the processing gas introduced from the gas introduction hole 36 formed in the center of the main body 31 to the peripheral side of the gas diffusion space 33 along an upper surface thereof. The processing gas, which has flowed to the peripheral portion along the upper surface of the baffle plate 34 in the gas diffusion space 33, further flows from the peripheral portion toward the center of a space between the baffle plate 34 and the shower plate 32, and is ejected toward the wafer W from the gas ejection holes 35. The baffle plate 34 may have a diameter equal to or larger than that of the wafer W.

The exhaust part 4 includes an exhaust pipe 41 connected to the exhaust port 13b of the exhaust duct 13, and an exhaust mechanism 42 connected to the exhaust pipe 41 and including a vacuum pump, a pressure control valve and the like. During the processing, the gas within the chamber 1 reaches the exhaust duct 13 via the slit 13a, and is exhausted from the exhaust duct 13 through the exhaust pipe 41 by the exhaust mechanism 42 of the exhaust part 4.

The processing gas supply mechanism 5 supplies the processing gas during the ALD-based film formation. The processing gas supply mechanism 5 includes a raw material gas source 51 configured to supply a raw material gas containing a constituent element of a film to be formed, a reaction gas source 52 configured to supply a reaction gas that reacts with the raw material gas, and first and second purge gas sources 53 and 54 configured to supply a purge gas. In addition, the processing gas supply mechanism 5 includes a raw material gas supply pipe 61 extending from the raw material gas source 51 and a reaction gas supply pipe 62 extending from the reaction gas source 52. In addition, the processing gas supply mechanism 5 includes a first purge gas supply pipe 63 extending from the first purge gas source 53 and a second purge gas supply pipe 64 extending from the second purge gas source 54.

The raw material gas supply pipe 61 and the reaction gas supply pipe 62 are joined in a pipe 66. The pipe 66 is connected to the gas introduction hole 36 described above. The first purge gas supply pipe 63 is connected to the raw material gas supply pipe 61, and the second purge gas supply pipe 64 is connected to the reaction gas supply pipe 62. The raw material gas supply pipe 61 is provided with a mass flow controller 71a as a flow rate controller and an opening/closing valve 71b. The reaction gas supply pipe 62 is provided with a mass flow controller 72a and an opening/closing valve 72b. The first purge gas supply pipe 63 is provided with a mass flow controller 73a and an opening/closing valve 73b. The second purge gas supply pipe 64 is provided with a mass flow controller 74a and an opening/closing valve 74b. The processing gas supply mechanism 5 is configured to be capable of performing a desired ALD process as described later by switching the opening/closing valves 71b and 72b.

By providing pipes that are respectively branched from the first purge gas supply pipe 63 and the second purge gas supply pipe 64 and increase a flow rate of the purge gas only at the time of purging, the processing gas supply mechanism 5 may increase the flow rate of the purge gas flow during the purging. As the purge gas, an inert gas, for example, a noble gas such as an Ar gas, a He gas or the like, or a N₂ gas, may be used.

As the raw material gas and the reaction gas, various gases may be used depending on a film to be formed. A predetermined film may be formed by causing the raw material gas to be adsorbed onto the front surface of the wafer and causing the reaction gas to react with the adsorbed raw material gas.

The plasma generation mechanism 6 is provided to form the reaction gas into a plasma when supplying the reaction gas and causing the reaction gas to react with the adsorbed raw material gas. The plasma generation mechanism 6 includes a power feed line 81 connected to the main body 31 of the shower head 3, a matcher 82 and a high-frequency power supply 83 connected to the power feed line 81, and an electrode 84 embedded in the susceptor 2. The electrode 84 is grounded. When high-frequency power is supplied from the high-frequency power supply 83 to the shower head 3, a high-frequency electric field is formed between the shower head 3 and the electrode 84, and the plasma of the reaction gas is generated by the high-frequency electric field. The matcher 82 matches a load impedance including the plasma with an internal (or output) impedance of the high-frequency power supply 83. The matcher 82 functions such that the output impedance of the high-frequency power supply 83 apparently coincides with the load impedance when plasma is generated inside the chamber 1.

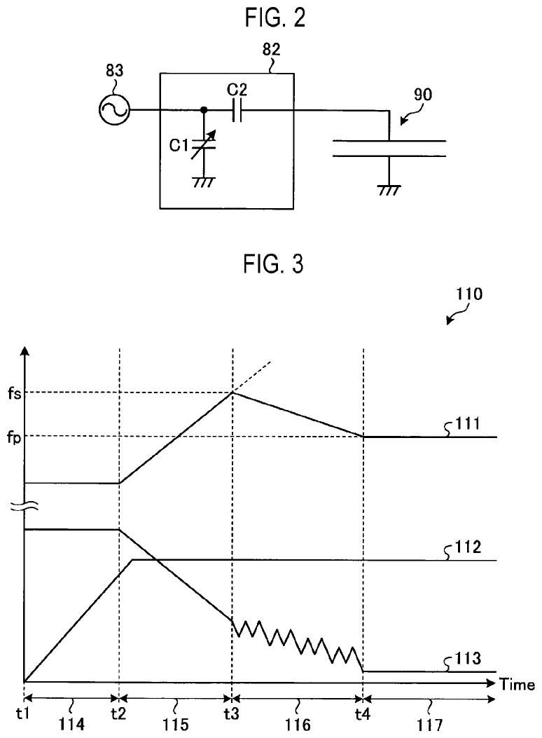

Now, the matcher 82 and the high-frequency power supply 83 will be described with reference to FIG. 2. FIG. 2 is a diagram illustrating an example in which the high-frequency power supply and the matcher according to the present embodiment are connected to each other. The matcher 82 and the high-frequency power supply 83, and a load 90 including a high-frequency electric field and plasma formed between the shower head 3 and the electrode 84 form a circuit as illustrated in FIG. 2. In the present embodiment, the matcher 82 is an inverted L-shaped matching circuit having a variable capacitor C1 connected in parallel with the load 90 and a capacitor C2 connected in series with the load 90. For example, the electrostatic capacitance of the variable capacitor C1 can be changed by controlling a stepping motor. The capacitor C2 is a fixed capacitor having a fixed electrostatic capacitance. The matcher 82 prevents a state in which the high-frequency power supply 83 and the matcher 82 try to match each other and not converge, by fixing the electrostatic capacitance of the capacitor C2. That is, in the matcher 82, the role of a capacitor connected in series with the load, which greatly changes the frequency in the conventional matcher, is performed by the high-frequency power supply 83, which is a variable frequency power supply. In addition, in FIG. 2, other elements such as an inductor, a capacitor and the like are omitted.

In the matcher 82, the variable capacitor C1 is automatically adjusted such that the reflected waves of the high-frequency power outputted from the high-frequency power supply 83 from the load 90 are minimized After the high-frequency power supply 83 determines that plasma is ignited, the matcher 82 performs the adjustment based on, for example, an instruction from the high-frequency power supply 83. In addition, the matcher 82 may automatically adjust the variable capacitor C1 after waiting for a time until the high-frequency power supply 83 ignites the plasma. In a first-round adjustment, the matcher 82 performs matching at a specified frequency fp at which plasma can be stably maintained, and holds a matching position. Since the matching position at the specified frequency fp is held in a second-round adjustment and subsequent adjustments, the matcher 82 corrects a time-dependent change of the matching condition at the specified frequency fp, for example, a long-term change in impedance in the chamber 1 due to an increase in the number of times of plasma ignition. That is, since the frequency of the high-frequency power outputted from the high-frequency power supply 83 is fixed at the specified frequency fp when the plasma is stable, the matcher 82 corrects a slight change in the matching condition corresponding to the long-term impedance change in the chamber 1.

The high-frequency power supply 83 is a variable frequency (VF) power supply that is capable of changing the frequency of the high-frequency power to be outputted. When the supply of the high-frequency power is started at a first frequency, which is a start frequency, the high-frequency power supply 83 sweeps the frequency such that the reflected waves from the load 90 are minimized. The start frequency may be, for example, 39 MHz. If it is determined that the plasma is ignited, the high-frequency power supply 83 changes the frequency of the high-frequency power to be supplied, from the second frequency that is an ignition frequency fs at which plasma is ignited, to a third frequency, which is the specified frequency fp at which plasma is capable of being stably maintained. Since the high-frequency power supply 83 is capable of performing the change from the ignition frequency fs to the specified frequency fp on the order of μs, a significant time delay does not occur. The high-frequency power supply 83 instructs the matcher 82 to perform the adjustment such that the reflected waves from the load 90 is minimized at the specified frequency fp. The specified frequency fp may be, for example, 40.68 MHz. In addition, the frequency of the high-frequency power outputted from the high-frequency power supply 83 may be appropriately set in a range of 450 kHz to 100 MHz depending on the raw material gas and the reaction gas.

The following is a description of FIG. 1. The controller 7 has a main controller, an input device, an output device, a display device, and a storage device. The main controller controls each component of the film forming apparatus 100, for example, the opening/closing valves 71b to 74b, the mass flow controllers 71a to 74a, the high-frequency power supply 83, the heater 21, the vacuum pump of the exhaust mechanism 42, and the like. The main controller performs control using, for example, a computer (central processing unit (CPU)). The storage device stores parameters of various processes performed by the film forming apparatus 100. In addition, a program for controlling a process executed by the film forming apparatus 100, that is, a storage medium storing a processing recipe is set in the storage device. The main controller calls a predetermined processing recipe stored in the storage medium, and controls the film forming apparatus 100 to execute a predetermined process, based on the processing recipe. For example, the controller 7 controls the opening/closing times of the opening/closing valves 71b and 72b so as to control the time for one-round supply of the raw material gas.

In the film forming apparatus 100 configured as described above, first, the gate valve 12 is opened, and the wafer W is loaded into the chamber 1 through the loading/unloading port 11 and placed on the susceptor 2 by the transfer device (not illustrated). The transfer device is retracted from the chamber 1, and the controller 7 raises the susceptor 2 to the processing position. Then, the controller 7 closes the gate valve 12, maintains the interior of the chamber 1 at a predetermined reduced pressure, and controls the temperature of the susceptor 2 to a predetermined temperature by the heater 21 depending on a film forming reaction when performing the ALD-based film formation.

In this state, the controller 7 opens the opening/closing valves 73b and 74b and continuously supplies the purge gas from the first purge gas source 53 and the second purge gas source 54 through the first purge gas supply pipe 63 and the second purge gas supply pipe 64, respectively. The controller 7 opens and closes the opening/closing valve 71b of the raw material gas supply pipe 61 and the opening/closing valve 72b of the reaction gas supply pipe 62 in an alternate and intermittent manner while continuously supplying the purge gas. In addition, the controller 7 turns on the high-frequency power supply 83 of the plasma generation mechanism 6 at the supply timing of the reaction gas.

The controller 7 sequentially repeats a raw material gas supply step (raw material gas+purge gas), a purge step (purge gas alone), a reaction gas supply step (reaction gas+purge gas+plasma), and a purge step (purge gas alone). Thus, predetermined film formation is performed through the PEALD. When the reaction gas has reactivity with the plasma, the reaction gas may be caused to constantly flow and only the plasma may be turned on/off during the film forming period.

Next, a process from plasma ignition to plasma maintenance will be described with reference to FIGS. 3 to 6. FIG. 3 is a diagram illustrating an example of the process from plasma ignition to plasma maintenance in the present embodiment. A graph 110 illustrated in FIG. 3 is a graph showing a frequency, a high-frequency power (dropping power), and a reflectance from when plasma is ignited till when the plasma is stabilized. A graph 111 shows the frequency of the high-frequency power outputted from the high-frequency power supply 83. A graph 112 shows the high-frequency power (dropping power) outputted from the high-frequency power supply 83. A graph 113 shows the reflectance of the high-frequency power from the load 90. In the graph 110, overshoot and undershoot are omitted.

At time t1, the controller 7 instructs the high-frequency power supply 83 to start outputting the high-frequency power. The high-frequency power supply 83 increases the high-frequency power to be supplied to a specified value in a time interval 114 from time t1 to time t2. In this case, the high-frequency power supply 83 may output high-frequency power obtained by adding power corresponding to reflected waves to traveling waves. When the high-frequency power rises to the specified value, the high-frequency power supply 83 sweeps the frequency such that the reflection from the load 90 is minimized. In the example of the graph 110, it can be seen that in a time interval 115 from time t2 to time t3, the graph 111 showing the frequency rises and the graph 113 showing the reflectance falls.

The high-frequency power supply 83 determines whether or not the reflectance is less than a threshold for determining plasma ignition. The threshold may be an arbitrary value at which the reflected waves are about 50% to 10% of the traveling waves. If it is determined that the reflectance is equal to or higher than the threshold, the high-frequency power supply 83 continuously sweeps the frequency. If it is determined at time t3 that the reflectance is less than the threshold, the high-frequency power supply 83 determines that the plasma has been ignited at the ignition frequency fs, which is the frequency at the time of the determination. If it is determined that the plasma has been ignited, the high-frequency power supply 83 changes the frequency of the high-frequency power from the ignition frequency fs to the specified frequency fp in a time interval 116 from time t3 to time t4.

After changing the frequency of the high-frequency power to the specified frequency fp, that is, in a time interval 117 after time t4, the high-frequency power supply 83 instructs the matcher 82 to perform adjustment such that the reflected waves from the load 90 are minimized at the specified frequency fp. Upon receiving the instruction from the high-frequency power supply 83, the matcher 82 adjusts the variable capacitor C1 such that the reflected waves from the load 90 are minimized while the plasma is maintained. When the process using the plasma is terminated, the controller 7 instructs the high-frequency power supply 83 to stop outputting the high-frequency power. When the output of the high-frequency power from the high-frequency power supply 83 is stopped, the matcher 82 holds the matching position of the variable capacitor C1. That is, in the present embodiment, the plasma ignition is performed with a high-speed variable frequency response of the high-frequency power supply 83, and the matcher 82 follows the time-dependent change of the film forming apparatus 100 without performing a high-speed response.

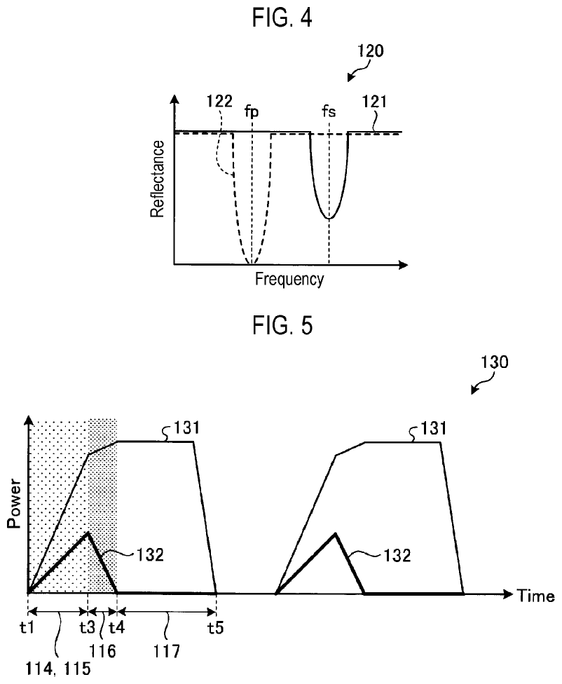

FIG. 4 is a diagram illustrating an example of a relationship between the frequency and the reflectance at the time of plasma ignition and at the time of plasma maintenance in the present embodiment. In a graph 120 illustrated in FIG. 4, the reflectance at the time of plasma ignition is shown by a graph 121, and the reflectance at the time of plasma maintenance is shown by a graph 122. As shown in the graph 121, at the time of plasma ignition, the ignition frequency fs has the lowest reflectance, and thus the plasma is easily ignited. Meanwhile, after the plasma is ignited, the specified frequency fp has the lowest reflectance and thus the plasma is stabilized. That is, the high-frequency power supply 83 is capable of stably maintaining the plasma by performing the plasma ignition at the ignition frequency fs and then changing the frequency to the specified frequency fp.

FIG. 5 is a diagram illustrating an example of the repetition of plasma ignition in the present embodiment. A graph 130 illustrated in FIG. 5 is a graph showing the high-frequency power in the repetition of the plasma ignition in the above-described reaction gas supply step (reaction gas+purge gas+plasma). A graph 131 shows the high-frequency power outputted from the high-frequency power supply 83. A graph 132 shows the power of reflected waves. In the graph 130, in the time intervals 114 and 115 from time t1 to time t3 when the plasma is ignited, the power of reflected waves increases depending on the increase in the high-frequency power. The graph 130 corresponds to an example of the case where the output of the high-frequency power is increased until the plasma ignition.

When the plasma is ignited at time t3, the high-frequency power supply 83 changes the frequency of the high-frequency power from the ignition frequency fs to the specified frequency fp in time interval 116 until time t4. In the time interval 117 from time t4 to time t5, the plasma is maintained. In the time interval 117, the matcher 82 performs matching between the traveling waves and the reflected waves of the high-frequency power. The matcher 82 mainly corrects a change in the matching condition due to a time-dependent change in the chamber 1. In the example of the graph 130, the time interval from the time t1 to t3 is about several tens of ms, and the time interval from time t1 to t5 is about several seconds, for example, about 2 to 4 seconds. As described above, in the present embodiment, since the high-frequency power supply 83 performs the matching at the time of plasma ignition, it is possible to ignite the plasma at high speed.

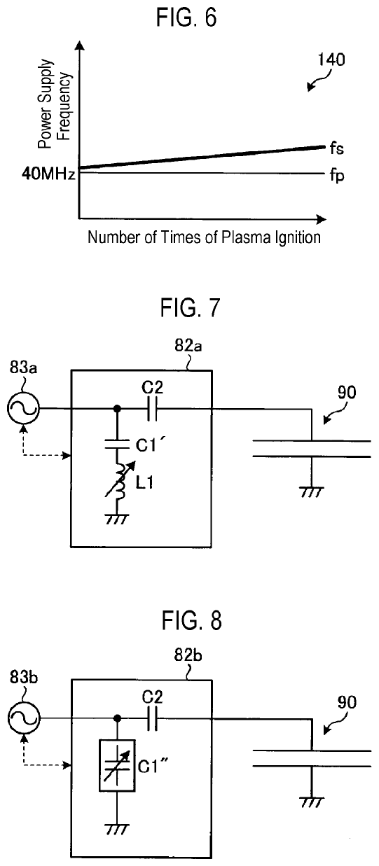

FIG. 6 is a diagram illustrating an example of time-dependent changes in the ignition frequency and the specified frequency in the present embodiment. A graph 140 illustrated in FIG. 6 is a graph showing a change in the ignition frequency fs due to a time-dependent change (the number of times of plasma ignition) in the chamber 1. As shown in the graph 140, when the film forming process is repeatedly performed, an internal state of the chamber 1 is changed due to deposition of a deposit or the like. Therefore, the ignition frequency fs changes from the specified frequency fp over time. The change in the ignition frequency fs is extremely short at the time of ignition, and thus does not affect the process characteristics.

### [Modification 1]

In the matching circuit of the matcher 82, a variable reactor that is capable of electrically changing inductance may be used instead of the variable capacitor C1. FIG. 7 is a diagram illustrating an example in which a high-frequency power supply and a matcher are connected to each other in Modification 1. A matcher 82a and a high-frequency power supply 83a of Modification 1 illustrated in FIG. 7 differ from the above-described embodiment in that a capacitor C1′ and a variable reactor (variable inductor) L1 are provided instead of the variable capacitor C1. The capacitor C1′ and the variable reactor L1 are connected in series. The capacitor C1′ is a capacitor having a fixed electrostatic capacitance. The variable reactor L1 is, for example, an inductor, of which inductance can be changed by being electrically controlled.

The matcher 82a is automatically adjusted, together with the high-frequency power supply 83a, based on an instruction from the high-frequency power supply 83a, such that the reflected waves of the high-frequency power outputted from the high-frequency power supply 83a from the load 90 are minimized.

The high-frequency power supply 83a is a VF power supply, which is capable of changing the frequency of the high-frequency power to be outputted. When the supply of the high-frequency power is started at a start frequency, the high-frequency power supply 83a sweeps the frequency such that the reflected waves from the load 90 are minimized. At this time, the high-frequency power supply 83a performs adjustment such that the high-frequency power supply 83a and the variable reactor L1 of the matcher 82a are integrally matched. If it is determined that the plasma is ignited, the high-frequency power supply 83a changes the frequency of the high-frequency power to be supplied, from the ignition frequency fs at which the plasma is ignited, to the specified frequency fp at which the plasma is capable of being stably maintained. In addition, the high-frequency power supply 83a instructs the matcher 82a to perform adjustment to, for example, a value at the time at which the plasma is stable such that the reflected waves from the load 90 is minimized at the specified frequency fp.

In Modification 1, since the variable reactor is electrically controlled, a high-speed operation is enabled, and is effective when the frequency of the high-frequency power is up to about 27 MHz.

### [Modification 2]

In the matching circuit of the matcher 82, a solid-state circuit, which switches a plurality of capacitors by electrical switching, may be used instead of the variable capacitor C1. FIG. 8 is a diagram illustrating an example in which a high-frequency power supply and a matcher are connected to each other in Modification 2. A matcher 82b and a high-frequency power supply 83b of Modification 2 illustrated in FIG. 8 differ from the above-described embodiment in that a solid-state circuit C1″ is provided instead of the variable capacitor C1. The solid-state circuit C1″ switches a plurality of capacitors by electrical switching, and thus may be regarded as a capacitor, of which electrostatic capacitance is capable of being changed.

The matcher 82b is automatically adjusted, together with the high-frequency power supply 83b, based on an instruction from the high-frequency power supply 83b, such that the reflected waves of the high-frequency power outputted from the high-frequency power supply 83b from the load 90 are minimized.

The high-frequency power supply 83b is a VF power supply, which is capable of changing the frequency of the high-frequency power to be supplied. When the supply of the high-frequency power is started at a start frequency, the high-frequency power supply 83b sweeps the frequency such that the reflected waves from the load 90 are minimized. At this time, the high-frequency power supply 83b performs adjustment such that the high-frequency power supply 83b and the solid-state circuit C1″ of the matcher 82b are integrally matched. If it is determined that the plasma is ignited, the high-frequency power supply 83b changes the frequency of the high-frequency power to be supplied, from the ignition frequency fs at which the plasma is ignited, to the specified frequency fp at which the plasma is capable of being stably maintained. In addition, the high-frequency power supply 83b instructs the matcher 82b to perform adjustment to, for example, a value at the time at which the plasma is stable such that the reflected waves from the load 90 become minimized at the specified frequency fp.

In Modification 2, since the solid-state circuit C1″ is controlled integrally with the high-frequency power supply 83b, a high-speed operation is enabled, and thus it is possible to suppress the reflected waves even at the time of start-up.

In Modifications 1 and 2, since the matchers 82a and 82b are also capable of responding at a high speed, matching is achieved at the ignition frequency fs without a change from the ignition frequency fs to the specified frequency fp, it is possible to stably maintain the plasma at the ignition frequency fs. In this case, the high-frequency power supplies 83a and 83b are capable of igniting the plasma at a higher speed by increasing power of the traveling waves by an amount corresponding to the reflected waves. That is, in Modifications 1 and 2, when it is not necessary to change the frequency to the specified frequency fp in the film forming process, it is possible to perform the plasma processing at the ignition frequency fs.

As described above, according to the present embodiment, the film forming apparatus 100 includes the high-frequency power supply 83 and the matcher 82. The high-frequency power supply 83 is a high-frequency power supply, which is capable of changing a frequency. The matcher 82 is a matcher that matches the internal impedance of the high-frequency power supply 83 and the load impedance of the load 90 including plasma. The matcher 82 has a capacitor having a fixed electrostatic capacitance and connected in series with the load 90. When the supply of high-frequency power is started at the first frequency, the high-frequency power supply 83 sweeps the frequency such that the reflected waves from the load 90 are minimized. If it is determined that plasma is ignited, the high-frequency power supply 83 changes the frequency of the high-frequency power to be supplied, from the second frequency at which the plasma is ignited to the third frequency at which the plasma is maintained, and instructs the matcher 82 to perform adjustment such that the reflected waves from the load 90 are minimized at the third frequency. As a result, it is possible to ignite the plasma at a high speed.

According to the present embodiment, the matcher 82 has a variable capacitor having a changeable electrostatic capacitance and connected in parallel with the load 90. The high-frequency power supply 83 instructs the matcher 82 to adjust the variable capacitor. As a result, the matcher 82 is capable of performing matching during the plasma maintenance.

According Modification 1, the matcher 82a includes a capacitor having a fixed electrostatic capacitance and a variable reactor, of which inductance is changeable. The capacitor and the variable reactor are connected in parallel with the load 90. The high-frequency power supply 83a instructs the matcher 82a to adjust the variable reactor. As a result, in Modification 1, a high-speed operation is enabled, and is effective when the frequency of the high-frequency power is up to about 27 MHz.

According to Modification 2, the matcher 82b has a solid-state circuit connected in parallel with the load 90 and capable of switching a plurality of capacitors. The high-frequency power supply 83b instructs the matcher 82b to adjust the solid-state circuit. As a result, a high-speed operation is enabled, and thus it is possible to suppress reflected waves even at the time of start-up.

According to the present embodiment, the third frequency is a frequency different from the second frequency. As a result, it is possible to maintain the plasma at the specified frequency fp.

According to Modifications 1 and 2, the third frequency is the same as the second frequency, and the high-frequency power supply 83a or 83b instructs the matcher 82a or 82b to perform adjustment such that the reflected waves from the load are minimized at the second frequency. As a result, it is possible to maintain the plasma at the ignition frequency fs.

### [Specific Example of ALD-based Film Formation]

In the ALD-based film formation of the present disclosure, a film to be formed is not particularly limited, and is applicable to all films which are formed through general ALD. As the raw material gas, a Si-containing gas, a B-containing gas, or a metal-containing gas containing a metal such as Ti, Al, Hf or the like may be used. As the reaction gas, an oxidizing gas, a nitriding gas, a carbonizing gas, a reducing gas, or the like may be used. In the case of using the oxidizing gas, it is possible to form an oxide film. In the case of using the nitriding gas, it is possible to form a nitride film. In the case of using the carbonizing gas, it is possible to form a carbonized film. In the case of using the reducing gas, it is possible to form a single film such as a metal film.

The raw material gas and the reaction gas are determined depending on the composition of a film to be formed. In the above-described embodiment, an example in which one type of raw material gas and one type of reaction gas are alternately supplied is illustrated. However, depending on the composition, multiple types of raw material gases or multiple types of reaction gases may be used. In this case, a processing gas supply mechanism configured to supply three or more types of gases may be used. These gases may be sequentially supplied in an appropriate supply pattern depending on the composition of a film to be formed. Depending on the supply pattern, multiple types of raw material gases or multiple types of reaction gases may be supplied in a continuous manner Even in such a case, the raw material gases and the reaction gases may be supplied in an alternate manner as a whole. In the case of using the multiple types of raw material gases or the multiple types of reaction gases, it is possible to form a composite film.

A specific example of the film to be formed may include an oxide film, such as a SiO₂ film, a TiO₂ film, a TiSiO₂ film, an Al₂O₃ film, or a HfO₂ film, a ZrO₂ film or the like. Example of the nitride film may include a TiN film, a SiN film, a TaN film, a BN film, a SiBN film and the like. Example of the carbonized film may include a SiC film, a TiAlC film, and the like. Examples of the single film such as a metal film may include a Ti film, a Ta film, a W film, a Si film and the like. Other examples of the film to be formed may include a SiON film, a SiOCN film, a SiBCN film, and the like.

In addition, in the above-described embodiment, the film forming apparatus 100, which performs a process such as film formation on the wafer W using a capacitively-coupled plasma source as a plasma source, has been described as an example, but the technology of the present disclosure is not limited thereto. Any plasma source is not limited to the capacitively-coupled plasma source as long as the plasma source is an apparatus that performs a process on the wafer W using plasma. Any plasma source such as an inductively-coupled plasma source, a microwave plasma source, a magnetron plasma source or the like may be used.

According to the present disclosure in some embodiments, it is possible to ignite plasma at a high speed.

It should be noted that the embodiments and modifications disclosed herein are exemplary in all respects and are not restrictive. The above-described embodiments may be omitted, replaced or modified in various forms without departing from the scope and spirit of the appended claims.

What is claimed is:

1. A film forming apparatus comprising:
a high-frequency power supply configured to be capable of changing a frequency; and
a matcher configured to match an internal impedance of the high-frequency power supply and a load impedance of a load including plasma, the matcher including a capacitor having a fixed electrostatic capacitance and connected in series with the load,
wherein, when the high-frequency power supply starts to supply a high-frequency power at a first frequency, the high-frequency power supply sweeps the frequency of the high-frequency power to be supplied such that reflected waves from the load are minimized, and
wherein, when it is determined that the plasma is ignited, the high-frequency power supply changes the frequency of the high-frequency power to be supplied, from a second frequency at which the plasma is ignited to a third frequency at which the plasma is maintained, and instructs the matcher to perform an adjustment such that the reflected waves from the load are minimized at the third frequency.

2. The film forming apparatus of claim 1, wherein the matcher further includes a variable capacitor having a changeable electrostatic capacitance and connected in parallel with the load, and
wherein the high-frequency power supply instructs the matcher to adjust the variable capacitor.

3. The film forming apparatus of claim 2, wherein the third frequency is a frequency different from the second frequency.

4. The film forming apparatus of claim 1, wherein the matcher further includes a capacitor having a fixed electrostatic capacitance and a variable reactor having a changeable inductance, the capacitor and the variable reactor being connected in parallel with the load, and
wherein the high-frequency power supply instructs the matcher to adjust the variable reactor.

5. The film forming apparatus of claim 4, wherein the third frequency is the same as the second frequency, and the high-frequency power supply instructs the matcher to perform the adjustment such that the reflected waves from the load are minimized at the second frequency.

6. The film forming apparatus of claim 1, wherein the matcher further includes a solid-state circuit connected in parallel with the load and configured to be capable of switching a plurality of capacitors, and
wherein the high-frequency power supply instructs the matcher to adjust the solid-state circuit.

7. The film forming apparatus of claim 6, wherein the third frequency is the same as the second frequency, and the high-frequency power supply instructs the matcher to perform the adjustment such that the reflected waves from the load are minimized at the second frequency.

8. The film forming apparatus of claim 1, wherein the third frequency is a frequency different from the second frequency.

9. A method of forming a film using a film forming apparatus,
wherein the film forming apparatus includes:
a high-frequency power supply configured to be capable of changing a frequency; and
a matcher configured to match an internal impedance of the high-frequency power supply and a load impedance of a load including plasma, the matcher including a capacitor having a fixed electrostatic capacitance and connected in series with the load,
the method comprising:
when the high-frequency power supply starts to supply a high-frequency power at a first frequency, sweeping, by the high-frequency power supply, the frequency of the high-frequency power to be supplied such that reflected waves from the load are minimized;
changing, when it is determined by the high-frequency power supply that the plasma is ignited, the frequency of the high-frequency power to be supplied, from a second frequency at which the plasma is ignited to a third frequency at which the plasma is maintained; and
instructing, by the high-frequency power supply, the matcher to perform an adjustment such that the reflected waves from the load are minimized at the third frequency.
